(19) United States
(12) Patent Application Publication
(10) Pub. No.: US 2005/0230803 A1
(43) Pub. Date: Oct. 20, 2005

(54) Leadframe packaging structure and the method of manufacturing the same

(76) Inventor: Chen-Chun Justin Liu, Taipei City (TW)

Correspondence Address: BIRCH STEWART KOLASCH & BIRCH, PO BOX 747, FALLS CHURCH, VA, 22040-0747, US

(21) Appl. No.: 10/864,368

(22) Filed: Jun. 10, 2004

(30) Foreign Application Priority Data
Apr. 14, 2004 (TW) 93110384

(51) Int. Cl. H01L 23/48; H01L 21/48

(52) U.S. Cl. 257/690; 438/123

(57) ABSTRACT

A leadframe packaging structure mainly includes a carrier consisting of more than one chip and a leadframe and provided with more than one connecting section; more than one terminal electrically connected to the chips;, and a packaging material applied to a top of the leadframe and the connecting sections to firmly connect to the leadframe via the connecting sections without the risk of separating therefrom.

### FIELD OF THE INVENTION

The present invention relates to a leadframe packaging structure, which mainly involves in the package of a leadframe, and more particularly to a packaging structure for interconnecting a packaging material with a leadframe. The present invention also relates to the method of manufacturing the leadframe packaging structure.

### BACKGROUND OF THE INVENTION

A conventional chip packaging structure is often subject to thermal expansion due to high amount of heat generated by the chip during operation, resulting in the following undesirable conditions in the packaging structure:
1. The packaging material is partially separated from the leadframe and become loosened; and
2. The packaging material and the leadframe are not effectively bonded together to cause separated packaging material and leadframe.

Referred to FIGS. 1, 2, and 3 that shows a conventional process for forming a leadframe packaging structure. As shown, the leadframe packaging structure mainly includes a carrier 11, more than one terminal 113, and a packaging material 12. The carrier 11 includes a leadframe 111 and a chip 112 mounted on the leadframe 111. A lead 113a is connected at an end with the terminal 113 and at the other end with a bonding pad 113b on the chip 112, so as to electrically connect the chip 112 to the terminals 113. The packaging material 12 is applied to a top of the leadframe 111. After the packaging material 12 is cooled and set, a leadframe packaging structure as shown in FIGS. 2 and 3 is obtained.

However, when the above product is in use, the high amount of heat generated by the chip 112 during operation frequently causes the packaging material to expand due to such heat and become loosened and partially separated from the leadframe 111. The packaging material 12 tends to completely separate from the leadframe 111 after a period of time and fails to protect the chip 112, resulting in an damaged chip 112.

In conclusion, the conventional leadframe packaging structure has the following drawbacks:
1. There is no way to prevent the packaging material from separating from the leadframe. The high amount of heat generated by the chip during operation thereof would inevitably subject the packaging material to thermal expansion and accordingly looseness and separation from the leadframe.
2. It is often found that the packaging material could not be effectively bonded to the leadframe, and must be applied again to remake the package, resulting in increased manufacturing cost.

It is therefore a very important issue to solve the above-mentioned problems and to enhance the bonding between the packaging material and the leadframe.

### SUMMARY OF THE INVENTION

A primary object of the present invention is to provide a leadframe packaging structure that enables firm connection of a packaging material with a leadframe.

Another object of the present invention is to provide a method of manufacturing a leadframe packaging structure that enables firm connection of a packaging material with a leadframe.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a conventional leadframe packaging structure before being packaged with a packaging material;

FIG. 2 is a perspective view of the conventional leadframe packaging structure of FIG. 1 after being packaged with a packaging material;

FIG. 3 is a sectioned side view of the conventional leadframe packaging structure of FIG. 2;

FIG. 4 is a perspective view of a leadframe packaging structure according to a first preferred embodiment of the present invention before being packaged with a packaging material;

FIG. 5 is a perspective view of the leadframe packaging structure of FIG. 4 after being packaged with a packaging material;

FIG. 6 is a sectioned side view of the leadframe packaging structure of FIG. 5;

FIG. 7 is a perspective view of a leadframe according to a second preferred embodiment of the present invention;

FIG. 8 is a perspective view of a leadframe according to a third preferred embodiment of the present invention;

FIG. 9 is a sectioned side view showing the leadframe according to the third preferred embodiment of the present invention is processed with a press;

FIG. 10 is a sectioned side view showing the leadframe according to the third preferred embodiment of the present invention is processed with a forming machine;

FIG. 11 is a sectioned side view of the leadframe according to the third preferred embodiment of the present invention after being processed;

FIG. 12 is a perspective view of a leadframe according to a fourth preferred embodiment of the present invention;

FIG. 13 is a sectioned side view showing the leadframe according to the fourth preferred embodiment of the present invention is processed with a press;

FIG. 14 is a sectioned side view showing the leadframe according to the fourth preferred embodiment of the present invention is processed with a forming machine;

FIG. 15 is a sectioned side view of the leadframe according to the fourth preferred embodiment of the present invention after being processed;

FIG. 16 is a perspective view of a leadframe according to a fifth preferred embodiment of the present invention;

FIG. 17 is a sectioned side view showing the leadframe according to the fifth preferred embodiment of the present invention is processed with a press;

FIG. 18 is a sectioned side view showing the leadframe according to the fifth preferred embodiment of the present invention is processed with a forming machine;

FIG. 19 is a sectioned side view of the leadframe according to the fifth preferred embodiment of the present invention after being processed;

FIG. 20 is a perspective view of a leadframe according to a sixth preferred embodiment of the present invention;

FIG. 21 is a sectioned side view showing the leadframe according to the sixth preferred embodiment of the present invention is processed with a press;

FIG. 22 is a sectioned side view showing the leadframe according to the sixth preferred embodiment of the present invention is processed with a forming machine;

FIG. 23 is a sectioned side view of the leadframe according to the sixth preferred embodiment of the present invention after being processed;

FIG. 24 is a perspective view showing a leadframe according to a seventh preferred embodiment of the present invention is processed with a press;

FIG. 25 is a perspective view showing the leadframe according to the seventh preferred embodiment of the present invention is processed with a forming machine;

FIG. 26 is a perspective view of the leadframe according to the seventh preferred embodiment of the present invention after being processed;

FIG. 27 is a perspective view showing a leadframe according to an eighth preferred embodiment of the present invention is processed with a press;

FIG. 28 is a perspective view showing the leadframe according to the eighth preferred embodiment of the present invention is processed with a forming machine;

FIG. 29 is a perspective view of the leadframe according to the eighth preferred embodiment of the present invention after being processed;

FIG. 30 is a perspective view showing a leadframe according to a ninth preferred embodiment of the present invention is processed with a press;

FIG. 31 is a perspective view showing the leadframe according to the ninth preferred embodiment of the present invention is processed with a forming machine;

FIG. 32 is a perspective view of the leadframe according to the ninth preferred embodiment of the present invention after being processed;

FIG. 33 is a perspective view showing a leadframe according to a tenth preferred embodiment of the present invention is processed with a press;

FIG. 34 is a perspective view showing the leadframe according to the tenth preferred embodiment of the present invention is processed with a forming machine; and

FIG. 35 is a perspective view of the leadframe according to the tenth preferred embodiment of the present invention after being processed.

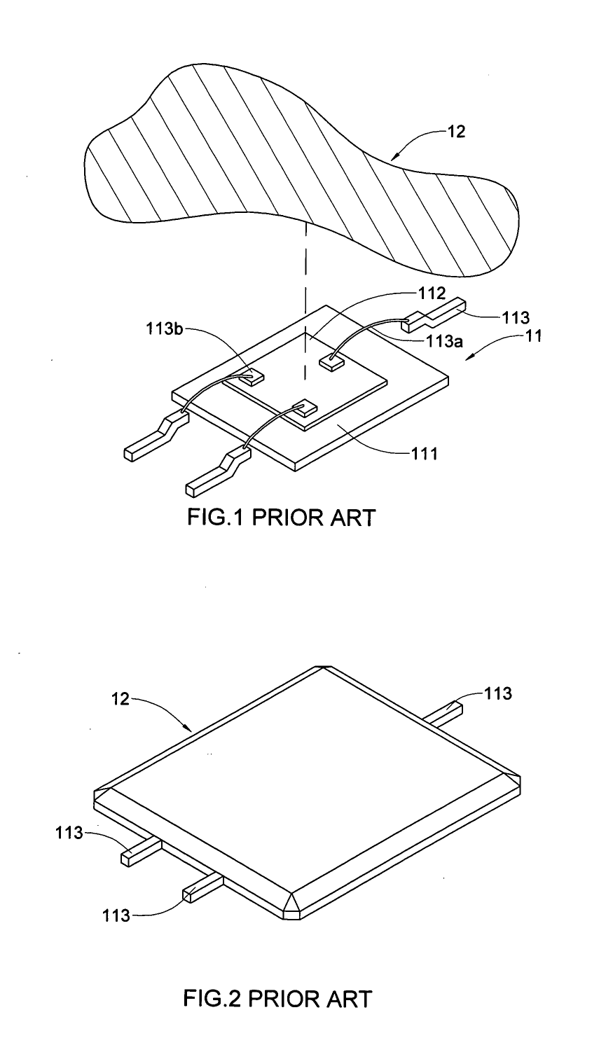

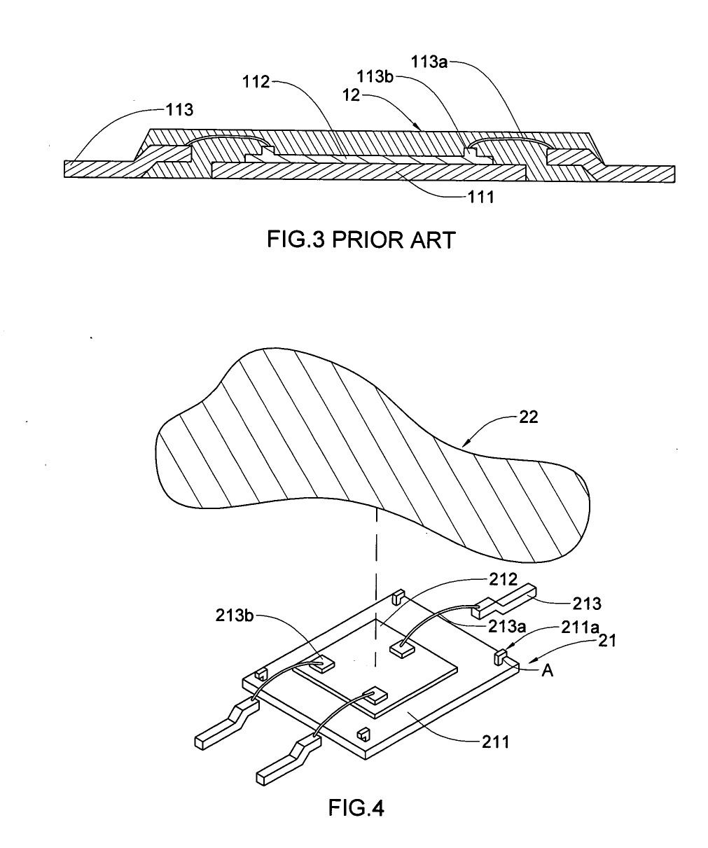

### DETAILED DESCRIPTION OF THE PREFERRED EMBODIMENTS

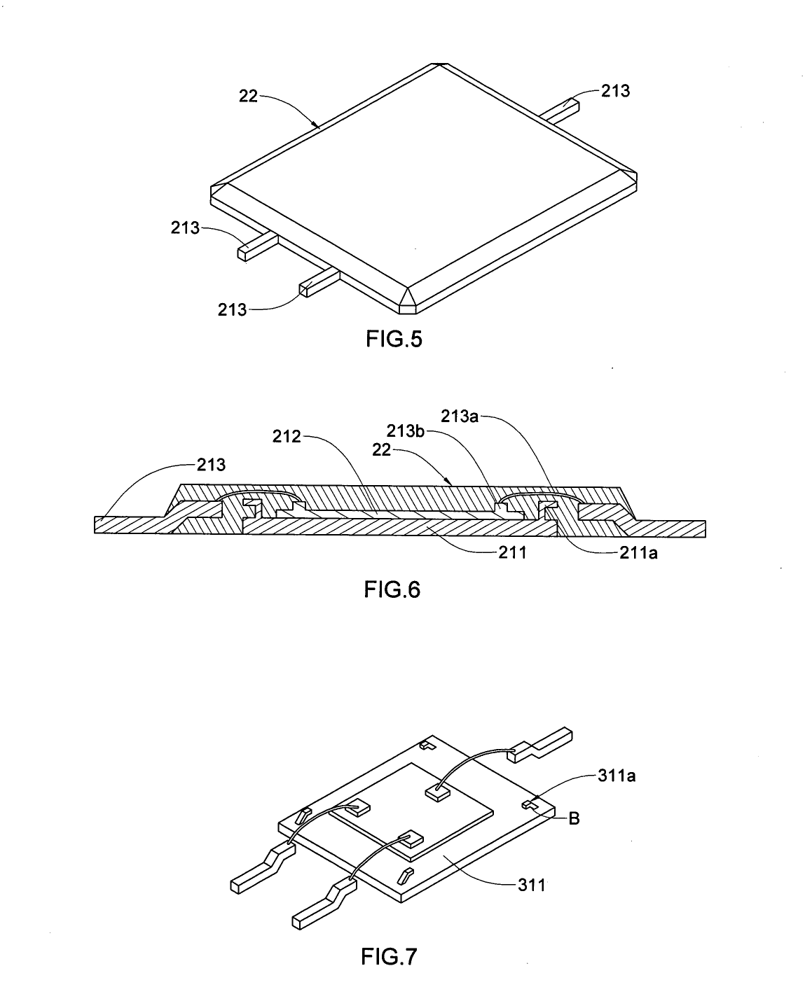

Please refer to FIGS. 4, 5, and 6 that shows a leadframe packaging structure according to a first preferred embodiment of the present invention. As shown, the leadframe packaging structure mainly includes a carrier 21, more than one terminal 213, and a packaging material 22. The carrier 21 includes a leadframe 211 and a chip 212 mounted on the leadframe 211. The leadframe 211 is made of a material with good malleability, conductivity, and heat radiating power. A lead 213a is connected at an end to the terminal 213, and at the other end to a bonding pad 213b on the chip 212 to electrically connect the chip 212 to the terminals 213. The leadframe 211 is configured with at least one connecting section 211a to enable firm association of the packaging material 22 with the leadframe 211 when the packaging material 22 is applied on a top of the leadframe 211. With the connecting sections 211a, the risk of having separated packaging material 22 and leadframe 211 is eliminated.

In the first preferred embodiment of the present invention, the connecting sections 211a are integrally formed on the leadframe 211. More specifically, the connecting section 211a is formed by processing the leadframe 211 with a press to obtain a preliminarily shaped connecting section 211a in the form of a substantially rectangular bar on the leadframe 211, and then bending the preliminarily shaped connecting section using a forming machine to obtain an upside-down L-shaped bar having a bend A.

With the connecting sections 211a having a bend A, the packaging material 22 applied to the top of the leadframe 211 and the connecting sections 211a on the leadframe 211 could firmly associate with the leadframe 211 without the risk of easily separating therefrom or becoming loosened relative to the leadframe 211. Particularly, an even better connecting effect can be achieved when a plurality of connecting sections 211a are simultaneously provided on the leadframe 211. Therefore, the number of the connecting sections 211a is not limited to two sets as shown in the drawings. In other words, multiple pieces or sets of connecting sections 211a may be provided on the leadframe 211.

Please refer to FIG. 7, in which a leadframe 311 according to a second preferred embodiment of the present invention is shown. The second embodiment has an overall structure generally the same as that of the first preferred embodiment, except for the connecting sections 311a thereof. The connecting section 311a is formed by pressing a thick parent material of the leadframe 311 using a press to obtain a preliminarily shaped connecting section 311a on the leadframe 311, and then bending the preliminarily shaped connecting section 311a with a forming machine to obtain an upside-down V-shaped bar having a bend B.

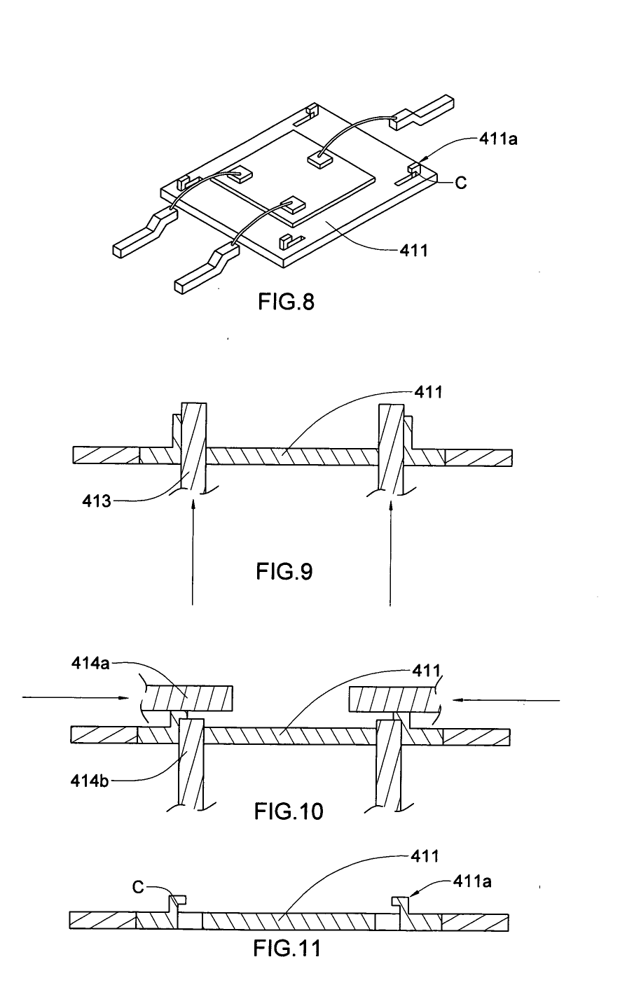

FIGS. 8, 9, 10, and 11 shows the forming of a leadframe 411 according to a third preferred embodiment of the present invention. The third embodiment has an overall structure generally the same as that of the first preferred embodiment, except for the connecting sections 411a thereof. As shown, the connecting section 411a is formed by punching and shearing a predetermined inner location on the leadframe 411 using a punching and shearing machine 413 to obtain a preliminarily shaped connecting section 411a, as shown in FIG. 9, and then bending the preliminarily shaped connecting section 411a using a forming machine 414a, 414b to obtain an upside-down L-shaped bar having a bend C.

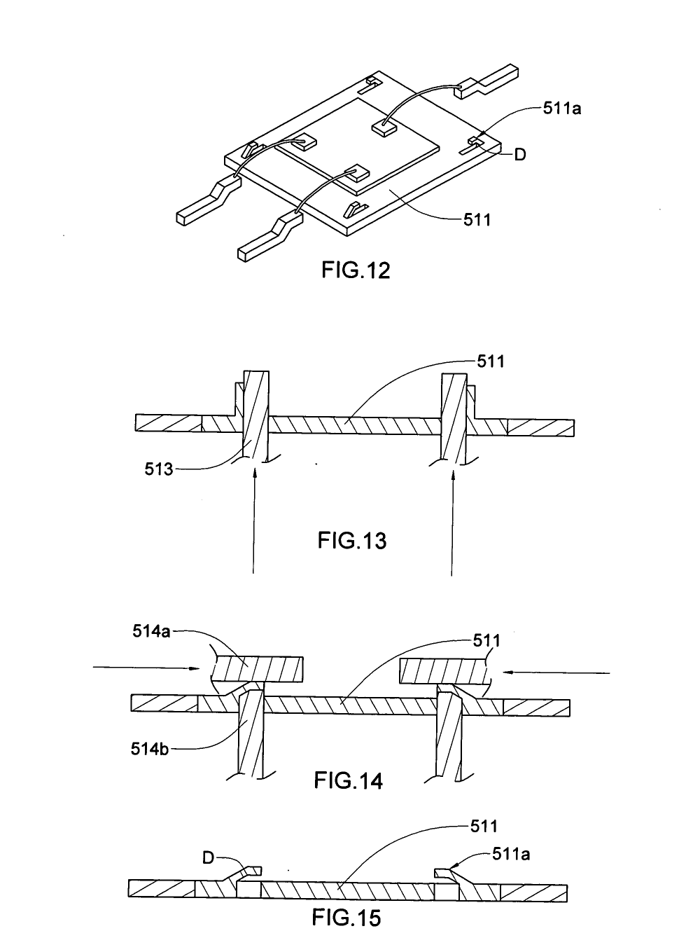

Please refer to FIGS. 12, 13, 14, and 15 that shows the process of forming a leadframe 511 according to a fourth preferred embodiment of the present invention. The fourth embodiment has an overall structure generally the same as that of the first preferred embodiment, except for the connecting sections 511a thereof. The connecting section 511a is formed by punching and shearing a predetermined inner location on the leadframe 511 using a punching and shearing machine 513 to obtain a preliminarily shaped connecting section as shown in FIG. 13, and then bending the preliminarily shaped connecting section using a forming machine 514a, 514b to obtain an upside-down V-shaped bar having a bend D.

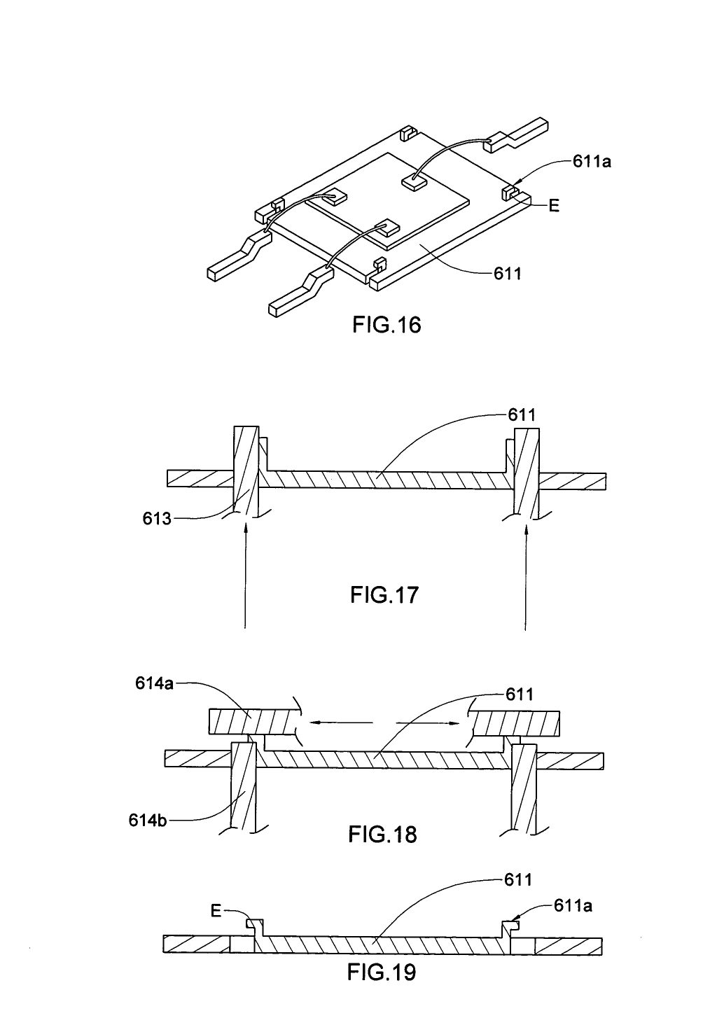

FIGS. 16, 17, 18, and 19 shows the process of forming a leadframe 611 according to a fifth preferred embodiment of the present invention. The fifth embodiment has an overall structure generally the same as that of the first preferred embodiment, except for the connecting sections 611a thereof. The connecting section 611a is formed by punching and shearing a predetermined location close to an outer edge of the leadframe 611 using a punching and shearing machine 613 to obtain a preliminarily shaped connecting section 611a as shown in the FIG. 17, and then bending the preliminarily shaped connecting section 611a using a forming machine 614a, 614b to obtain an upside-down L-shaped bar having a bend E.

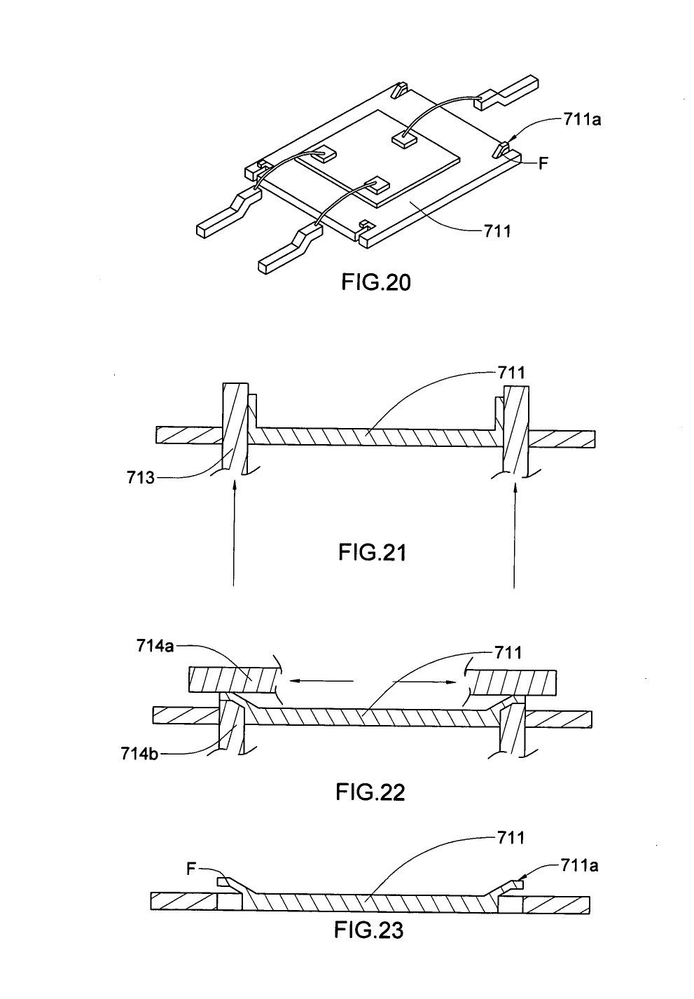

Please refer to FIGS. 20, 21, 22, and 23 that shows the process of forming a leadframe 711 according to a sixth preferred embodiment of the present invention. The sixth embodiment has an overall structure generally the same as that the first preferred embodiment, except for the connecting sections 711a thereof. The connecting section 711a is formed by punching and shearing the leadframe 711 at a predetermined location close to an outer edge thereof using a punching and shearing machine 713 to obtain a preliminarily shaped connecting section 711a, as shown in FIG. 21, and then bending the preliminarily shaped connecting section using a forming machine 714a, 714b to obtain an upside-down V-shaped bar having a bend F.

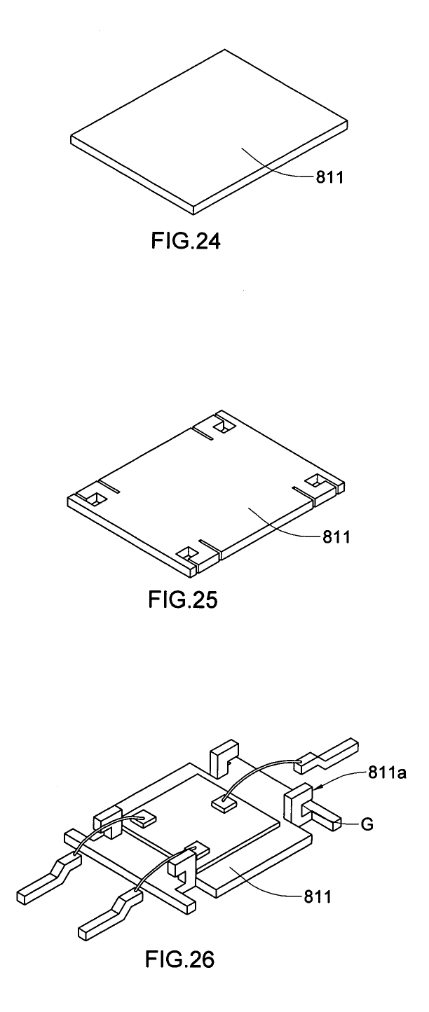

Please refer to FIGS. 24, 25, and 26 that shows the forming of a leadframe 811 according to a seventh preferred embodiment of the present invention. The seventh embodiment has an overall structure generally same as that of the first preferred embodiment, except for the connecting sections 811a thereof. The connecting section 811a is formed by punching and shearing a predetermined location close to an outer edge of the leadframe 811 using a punching and shearing machine to obtain a preliminarily shaped connecting section 811a, as shown in FIGS. 24 and 25, and then bending the preliminarily shaped connecting section using a forming machine to obtain an upside-down L-shaped bar having a bend G as shown in FIG. 26.

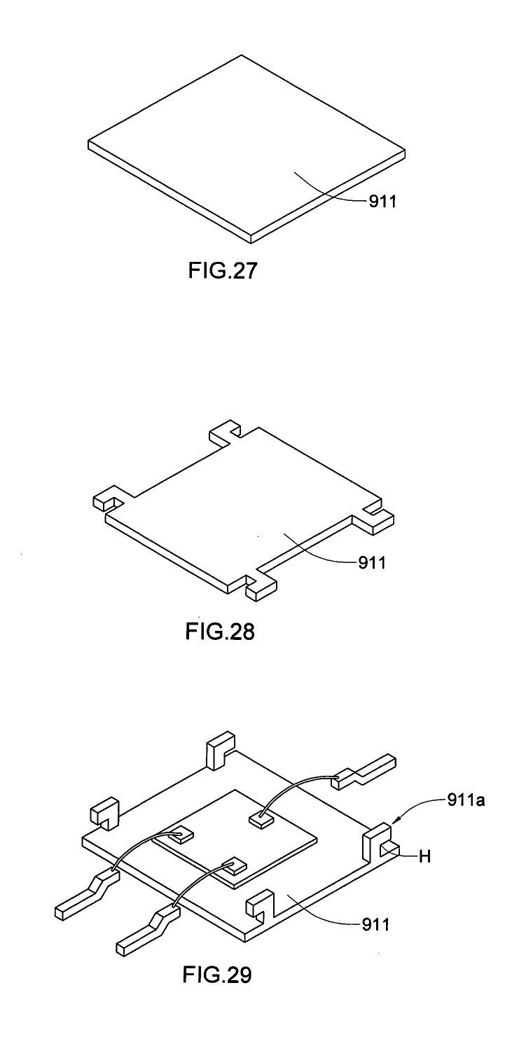

FIGS. 27, 28, and 29 shows the forming of a leadframe 911 according to an eighth preferred embodiment of the present invention. The eighth embodiment has an overall structure generally the same as that of the first preferred embodiment, except for the connecting sections 911a thereof. The connecting section 911a is formed by punching a predetermined location close to an outer edge of the leadframe 911 using a punching and shearing machine, as shown in FIG. 27, to obtain a preliminarily shaped connecting section 911a as shown in FIG. 28, and then bending the preliminarily shaped connecting section 911a to obtain an upside-down L-shaped bar having a bend H as shown in FIG. 29.

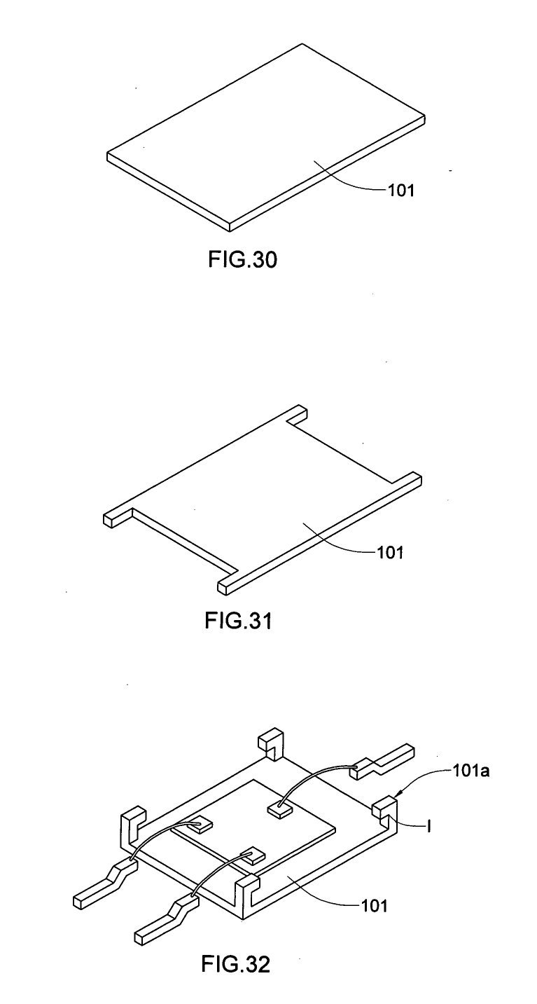

Please refer to FIGS. 30, 31, and 32 that shows the forming of a leadframe 101 according to a ninth preferred embodiment of the present invention. The ninth embodiment has an overall structure generally the same as that of the first preferred embodiment, except for the connecting sections 101a thereof. The connecting section 101a is formed by punching and shearing a predetermined location close to an outer edge of the leadframe 101 using a punching and shearing machine, as shown in FIG. 30, to obtain a preliminarily shaped connecting section 101a as shown in FIG. 31, and then bending the preliminarily shaped connecting section 101a using a forming machine to obtain an upside-down L-shaped bar having a bend I as shown in FIG. 32.

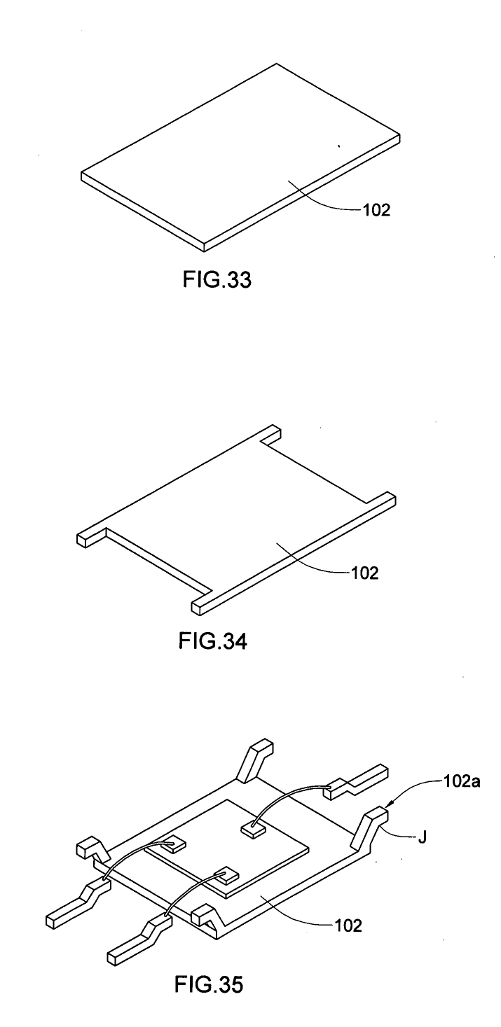

FIGS. 33, 34, and 35 shows the forming of a leadframe 102 according to a tenth preferred embodiment of the present invention. The tenth embodiment has an overall structure generally the same as that of the first preferred embodiment, except for the connecting sections 102a thereof. The connecting section 102a is formed by punching and shearing a predetermined location close to an outer edge of the leadframe 102 of FIG. 33 using a punching and shearing machine to obtain a preliminarily shaped connecting section 102a as shown in FIG. 34, and then bending the preliminarily shaped connecting section using a forming machine to obtain an upside-down V-shape bar having a bend J as shown in FIG. 35.

The present invention has been described with some preferred embodiments thereof and it is understood that many changes and modifications in the described embodiments can be carried out without departing from the scope and the spirit of the invention that is intended to be limited only by the appended claims.

1. A leadframe packaging structure, comprising a carrier, more than one terminal, and a packaging material; said carrier including more than one chip, a leadframe for said chips to mount thereon, and more than one connecting section; said terminals and said chips being electrically connected to one another; and said packaging material being applied to a top of said leadframe and said connecting sections and being firmly connected to said leadframe via said connecting sections without the risk of separating from said leadframe.

2. The leadframe packaging structure as claimed in claim 1, wherein said leadframe is made of a material having good malleability.

3. The leadframe packaging structure as claimed in claim 1, wherein said leadframe is made of a material having good conductivity.

4. The leadframe packaging structure as claimed in claim 1, wherein said leadframe is made of a material having good heat radiating power.

5. The leadframe packaging structure as claimed in claim 1, wherein said terminal and said chip are connected to one another via a lead.

6. The leadframe packaging structure as claimed in claim 5, wherein said lead is connected to said chip via a bonding pad.

7. The leadframe packaging structure as claimed in claim 1, wherein said connecting section is an upside-down L-shaped member.

8. The leadframe packaging structure as claimed in claim 1, wherein said connecting section is an upside-down V-shaped member.

9. A method of manufacturing a leadframe packaging structure, comprising the steps of:
(a) using a press to form more than one preliminarily shaped connecting section on a leadframe;
(b) using a forming machine to process said preliminarily shaped connecting sections on said leadframe to form more than one connecting section; and
(c) applying a packaging material to a top of said leadframe and said connecting sections, so that said packaging material is firmly connected to said leadframe via said connecting sections.

10. A method of manufacturing a leadframe packaging structure, comprising the steps of:
(a) using a punching and shearing machine to form more than one preliminarily shaped connecting section on a leadframe;
(b) using a forming machine to process said preliminarily shaped connecting sections on said leadframe to form more than one connecting section on said leadframe; and
(c) applying a packaging material to a top of said leadframe and said connecting sections, so that said packaging material is firmly connected to said leadframe via said connecting sections.
